(19) United States
(12) Patent Application Publication
(10) Pub. No.: US 2005/0258536 A1
(43) Pub. Date: Nov. 24, 2005

(54) Chip heat sink device and method

(75) Inventors: Kuo-Wei Lin, Chudon (TW); Hsaio-Ping Chang, Hsin Chu (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/851,576

(22) Filed: May 21, 2004

(51) Int. Cl. H01L 23/34

(52) U.S. Cl. 257/717

(57) ABSTRACT

An IC chip heat sink and method for dissipating heat from an integrated circuit (IC) chip, is disclosed. In a typical embodiment, the IC chip heat sink is fabricated by depositing a metal seed layer on the backside of a semiconductor wafer having multiple IC chips fabricated thereon. A photoresist layer is then deposited on the seed layer and patterned to define multiple photoresist openings. Multiple columns are formed on the seed layer by the electrochemical plating of a metal in the photoresist openings. Finally, the photoresist is stripped from the seed layer to define the multiple columns, which extend from the seed layer, and a network of heat sink channels between the columns. During functioning of the chip, heat is dissipated from the chip through the heat sink.

### FIELD OF THE INVENTION

The present invention relates to flip chip packaging of semiconductor integrated circuits. More particularly, the present invention relates to a new and improved chip heat sink device and method for dissipating heat from a functioning IC chip.

### BACKGROUND OF THE INVENTION

One of the last processes in the production of semiconductor integrated circuits (ICs) is multi-leveled packaging, which includes expanding the electrode pitch of the IC chips containing the circuits for subsequent levels of packaging; protecting the chip from mechanical and environmental stress; providing proper thermal paths for channeling heat dissipated by the chip; and forming electronic interconnections. The manner in which the IC chips are packaged dictates the overall cost, performance, and reliability of the packaged chips, as well as of the system in which the package is applied.

Package types for IC chips can be broadly classified into two groups: hermetic-ceramic packages and plastic packages. A chip packaged in a hermetic package is isolated from the ambient environment by a vacuum-tight enclosure. The package is typically ceramic and is utilized in high-performance applications. A chip packaged in a plastic package, on the other hand, is not completely isolated from the ambient environment because the package is composed of an epoxy-based resin. Consequently, ambient air is able to penetrate the package and adversely affect the chip over time. Recent advances in plastic packaging, however, has expanded their application and performance capability. Plastic packages are cost-effective due to the fact that the production process is typically facilitated by automated batch-handling.

A recent development in the packaging of IC chips is the ball grid array (BGA) package, which may be utilized with either ceramic packages or plastic packages and involves different types of internal package structures. The BGA package uses multiple solder balls or bumps for electrical and mechanical interconnection of IC chips to other microelectronic devices. The solder bumps, which are formed on each IC chip or die after the die are cut from a single wafer, serve to both secure the IC chip to a circuit board and electrically interconnect the chip circuitry to a conductor pattern formed on the circuit board. The BGA technique is included under a broader connection technology known as “Controlled Collapse Chip Connection-C4” or “flip-chip” technology.

Flip chip technology can be used in conjunction with a variety of circuit board types, including ceramic substrates, printed wiring boards, flexible circuits, and silicon substrates. The solder bumps are typically located at the perimeter of the flip chip on electrically conductive bond pads that are electrically interconnected with the circuitry on the flip chip. Because of the numerous functions typically performed by the microcircuitry of a flip chip, a relatively large number of solder bumps are often required. The size of a flip chip is typically on the order of about thirteen millimeters per side, resulting in crowding of the solder bumps along the perimeter of the flip chip. Consequently, flip chip conductor patterns are typically composed of numerous individual conductors that are often spaced apart about 0.1 millimeter or less.

A section of a typical conventional flip chip 26 is shown schematically in FIG. 1 and includes, for example, an upper conductive layer 16 which is separated from an underlying conductive layer 22 by an insulative layer 18. Multiple underlying conductive layers 22 are separated from each other by an insulative layer 18. The conductive layers 16, 22 are disposed in electrical contact with each other through conductive vias 20 that extend through the insulative layers 18. The various insulative layers 18 and conductive layers 22 are sequentially deposited on a silicon substrate 24 throughout semiconductor fabrication, in conventional fashion.

After fabrication of multiple IC circuit chips or die in the insulative layers 18 and conductive layers 22 deposited on a single semiconductor wafer substrate 24 is completed, the individual die are cut from the substrate 24. Multiple solder bumps 10 are then soldered directly to the continuous upper surfaces of respective bump pads 14, each of which is typically rectangular in configuration and partially covered by a passivation layer 12. The bump pads 14 are surrounded by a dielectric layer 15 such as an oxide in the chip 26. As further shown in FIG. 1, each of the bump pads 14 is provided in electrical contact with the upper conductive layer 16.

As shown in FIG. 1B, after the solder bumps 10 are formed on the flip chip 26, the chip 26 is inverted (thus the term, “flip chip”) and the solder bumps 10 are bonded to electrical terminals in a substrate 28, such as a printed circuit board. Finally, a metal heat sink 30 is attached to the backside 25 of the substrate 24 of the flip chip 26, to dissipate heat during operation of the IC device of which the flip chip 26 is a part. The heat sink 30 includes multiple heat-dissipating slots 32 and is bonded to the substrate backside 25 typically using a spreader glue 34 loaded with silver particles. A metal cap 36 is typically sandwiched between the spreader glue 34 and the substrate backside 25.

Several disadvantages are associated with the conventional method for attaching a heat sink to an IC chip. One of these is the high cost associated with attaching a heat sink to each of the packaged die after die separation and packaging. Another is the large size of the resulting chip package. Accordingly, a new and improved chip heat sink device and method is needed which is characterized by low cost and a small package size.

An object of the present invention is to provide a novel heat sink which is applicable to integrated circuit chips.

Another object of the present invention is to provide a novel IC chip heat sink which is characterized by small package size.

Still another object of the present invention is to provide an IC chip heat sink which is characterized by low cost.

Another object of the present invention is to provide a novel IC chip heat sink which has a high heat transfer rate per unit area.

A still further object of the present invention is to provide a novel IC chip heat sink and method which may be simultaneously applied to all IC chips or die on a wafer substrate in successive process steps.

### SUMMARY OF THE INVENTION

In accordance with these and other objects and advantages, the present invention is generally directed to a novel IC chip heat sink which is characterized by low cost and efficient heat transfer rate per unit area, and contributes to a small chip package size. In a typical embodiment, the IC chip heat sink is fabricated by depositing a metal seed layer on the backside of a semiconductor wafer having multiple IC chips fabricated thereon. A photoresist layer is then deposited on the seed layer and patterned to define multiple photoresist openings. Multiple columns are formed on the seed layer by the electrochemical plating of a metal in the photoresist openings. Finally, the photoresist is stripped from the seed layer to define the multiple columns, which extend from the seed layer, and a network of heat sink channels between the columns.

The present invention further includes a method for dissipating heat from an IC chip during operation of an electronic product of which the IC chip is a part. In a typical embodiment, the method includes providing a semiconductor wafer; fabricating multiple IC chips on the wafer; depositing a metal seed layer on the backside of the wafer; depositing a photoresist layer on the seed layer; patterning multiple photoresist openings in the photoresist layer; depositing a metal into the photoresist openings and onto the seed layer; stripping the photoresist layer from the seed layer; separating the IC chips, such that an IC chip heat sink remains on the backside of each chip; packaging each of the IC chips into an electronic product; and dissipating heat from each IC chip through the heat sink during operation of the electronic product.

### BRIEF DESCRIPTION OF THE DRAWINGS

The invention will now be described, by way of example, with reference to the accompanying drawings, in which:

FIG. 1A is a cross-section of a portion of a semiconductor wafer substrate, illustrating a solder bump provided in electrical communication with conductive layers deposited on the substrate in a conventional BGA (ball grid array) IC chip packaging configuration;

FIG. 1B is a schematic illustrating conventional packaging of an IC flip chip and a conventional heat sink provided on the backside of the chip;

FIG. 2 is a cross-section of an IC flip chip, with a heat sink provided on the backside of the chip according to the present invention;

FIG. 3 is a top view, partially in section, of the heat sink of the IC flip chip of FIG. 2;

FIGS. 4A-4G are cross-sectional views of an IC flip chip, illustrating sequential process steps carried out to fabricate a heat sink on the backside of the flip chip according to the method of the present invention;

FIG. 5 is a flow diagram which summarizes sequential process steps according to the method of the present invention; and

FIG. 6 is a flow diagram which summarizes sequential process steps according to an alternative method of the present invention.

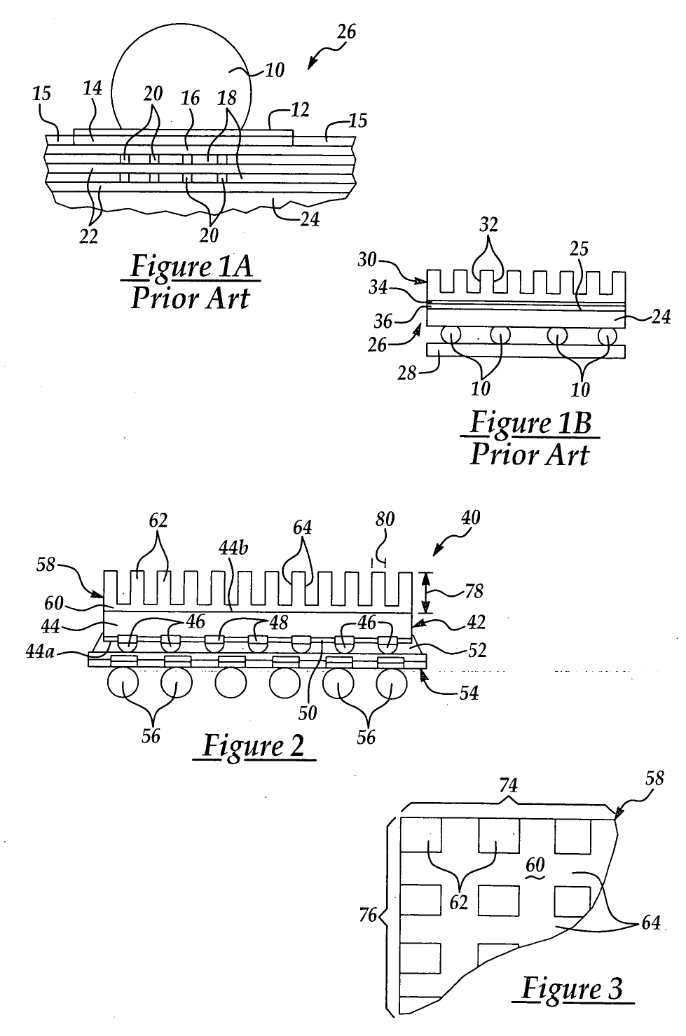

### DETAILED DESCRIPTION OF THE INVENTION

The present invention contemplates a novel IC chip heat sink which is fabricated by initially depositing a metal seed layer on the backside of a semiconductor wafer after multiple IC chips are fabricated on the wafer. A photoresist layer deposited on the seed layer is patterned to include multiple photoresist openings. Multiple columns are formed on the seed layer typically by the electrochemical plating of a metal in the photoresist openings. Finally, the photoresist is stripped from the seed layer and the photoresist openings to define the multiple columns, which extend from the seed layer, and a meshwork of heat sink channels between the columns. The heat sink is characterized by a high heat transfer rate per unit area between the semiconductor wafer substrate and the chip environment and contributes to a small chip package size in the finished electronic product.

The present invention further contemplates a method for dissipating heat from an IC chip during operation of an electronic product of which the IC chip is a part. The method includes providing a semiconductor wafer; fabricating multiple IC chips on the wafer; depositing a metal seed layer on the backside of the wafer; depositing a photoresist layer on the seed layer; patterning multiple photoresist openings in the photoresist layer; depositing a metal into the photoresist openings and onto the seed layer; stripping the photoresist layer from the seed layer; separating the IC chips, such that an IC chip heat sink remains on the backside of each chip; packaging each of the IC chips into an electronic product; and dissipating heat from each IC chip through the heat sink during operation of the electronic product. The method is characterized by low cost and is capable of simultaneous application to all IC chips or die on a wafer substrate in successive process steps.

Referring to FIGS. 2 and 3, an illustrative embodiment of a flip chip 40, on which is provided an IC chip heat sink 58 of the present invention, is shown. The flip chip 40 includes an IC chip 42 having a typically silicon semiconductor wafer 44 with a patterned surface 44a, which is typically covered by a passivation layer 50, and a wafer backside 44b. Throughout the course of semiconductor fabrication, multiple integrated circuits (not shown) are progressively fabricated on the patterned surface 44a. Solder bumps 46 are provided in electrical communication with the integrated circuits (ICs) through respective bump pads 48 on the patterned surface 44a, as is known by those skilled in the art.

During packaging, and typically after fabrication of the IC chip heat sink 58 thereon, the IC chip 42 is inverted and the solder bumps 46 are provided in electrical contact with a substrate 54, such as a printed circuit board, for example, for use in an electronic product. Typically, the IC chip 42 is attached to the substrate 54 using an epoxy 52. The substrate 54 is, in turn, provided in electrical contact with additional circuitry (not shown) in the electronic product through solder bumps 56. The packaging and assembly steps are carried out according to techniques which are well-known by those skilled in the art.

The IC chip heat sink 58 of the flip chip 40 is fabricated of a metal having a high thermal conductivity. Metals which are suitable for fabrication of the IC chip heat sink 58 include copper, silver and titanium, in non-exclusive particular. The IC chip heat sink 58 includes a metal seed layer 60 which is provided on the backside 44b of the semiconductor wafer 44. Multiple columns 62 extend perpendicularly from the planar surface of the seed layer 60, in adjacent, spaced-apart relationship to each other. As shown in FIG. 3, the adjacent columns 62 are arranged in a matrix of intersecting rows 74 and lines 76, defining a meshwork of intersecting heat sink channels 64. As shown in FIG. 2, each of the columns 62 has a column height 78 of typically at least about 100 μm and a column width 80 of typically about 10-100 μm.

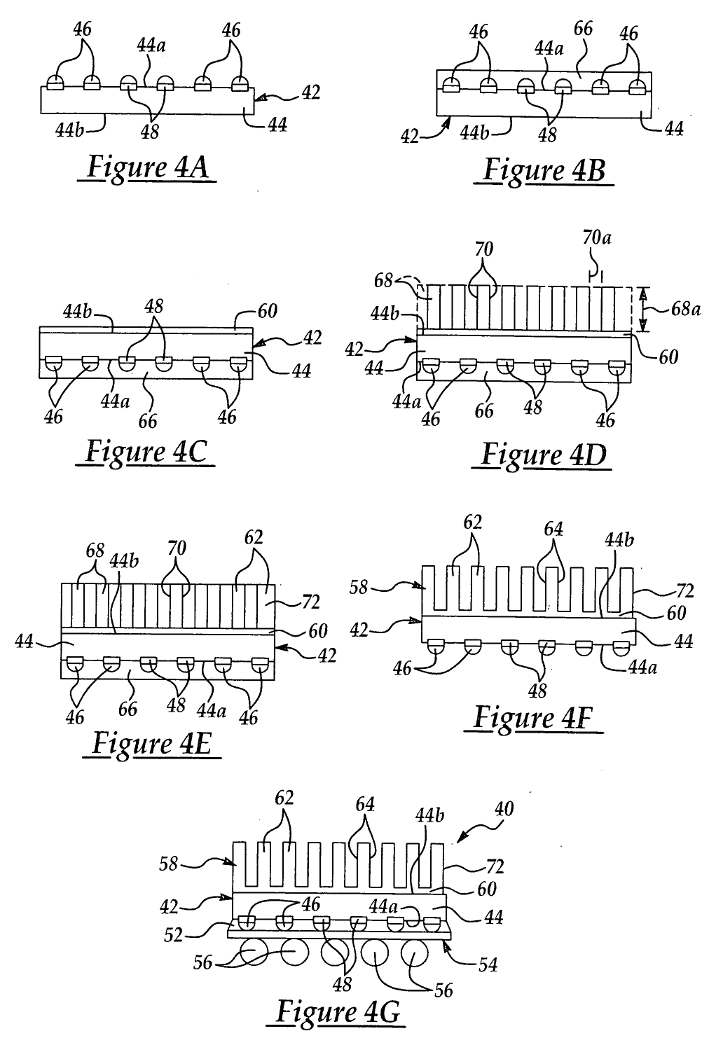

Referring next to FIGS. 4A-4G, wherein fabrication of an IC heat sink 58 on an IC chip 42 is shown. In FIGS. 4A-4G, a single IC chip 42 is shown for brevity. According to the method of the present invention, however, the IC chip heat sink 58 is typically formed on the entire backside 44b of the semiconductor wafer 44 prior to separation of individual IC chips 42 from each other. Accordingly, after the die cutting and separation process, an IC chip heat sink 58 remains on each of the IC chips 42, as hereinafter further described.

According to the method of the present invention, the IC chip heat sink 58 is fabricated typically as follows. First, throughout the course of semiconductor fabrication, integrated circuits (not shown) are fabricated on the patterned surface 44a of the semiconductor wafer 44. Bond pads 48 are provided in electrical contact with the integrated circuits of each IC chip 42. Solder bumps 46 are, then formed on the respective bond pads 48, as shown in FIG. 4A.

Next, as shown in FIG. 4B, a protective film laminate 66, is deposited on the patterned surface 44a to cover and protect the solder bumps 46 during fabrication of the IC chip heat sink 58. The protective film laminate 66 has a thickness which is sufficient to cover the solder bumps 46 and may be deposited on the patterned surface 44a using conventional CVD (chemical vapor deposition) techniques known by those skilled in the art.

As shown in FIG. 4C, the IC chip 42 is next inverted and a metal seed layer 60 is deposited on the backside 44b of the semiconductor wafer 44. The metal seed layer 60 may be copper, silver, titanium or any other thermally-conductive metal. The seed layer 60 is deposited on the wafer backside 44b typically using a conventional physical vapor deposition (PVD) sputter process.

As shown in FIG. 4D, a photoresist layer 68, which is typically a dry film resist (DFR), is deposited on the metal seed layer 60. The photoresist layer 68 preferably has a thickness 68a of at least typically about 100 μm. The photoresist layer 68 is then patterned to form multiple photoresist openings 70 which correspond in size and location to the respective columns 62 (FIG. 2) to be subsequently formed on the seed layer 60. Each of the photoresist openings 70 has a width 70a of typically about 10-100 μm.

As shown in FIG. 4E, a metal layer 72 is next deposited on the seed layer 60 and fills the photoresist openings 70 of the photoresist layer 68. The metal layer 72 is deposited on the seed layer 60 typically using conventional electrochemical plating techniques. The thickness of the metal layer 72 substantially corresponds to the thickness 68a of the photoresist layer 68. After completion of the electrochemical plating process, the metal layer 72 may be subjected to chemical mechanical planarization (CMP) to planarize and remove metal overburden from the metal layer 72, as necessary.

As shown in FIG. 4F, fabrication of the IC chip heat sink 58 is completed by next stripping the photoresist layer 68 from the seed layer 60. Accordingly, the columns 62 of the IC chip heat sink 58 extend from the seed layer 60, in substantially perpendicular relationship to the plane of the seed layer 60. Simultaneously, the protective film laminate 66 may be stripped from the patterned surface 44a of the semiconductor wafer 44. Alternatively, the protective film laminate 66 may be removed from the semiconductor wafer 44 in a separate process step.

After completion of the heat sink fabrication process, as heretofore described, a continuous heat sink 58 covers substantially the entire backside 44b of the intact semiconductor wafer 44, including the backsides of all IC chips 42 prevously fabricated on the wafer 44. The multiple IC chips 42 fabricated on the semiconductor wafer 44 are then separated from each other by cutting the semiconductor wafer 44 and heat sink 58 along scribe lines (not shown), according to techniques which are well-known by those skilled in the art. After the chip separation process, an IC chip heat sink 58 remains on the backside of each IC chip 42.

As shown in FIG. 4G, assembly of each flip chip 40 is then completed by attaching the solder bumps 46 of each IC chip 42 to the substrate 54, typically using the epoxy 52. The flip chip 40 is then assembled into the electronic product (not shown), according to the knowledge of those skilled in the art.

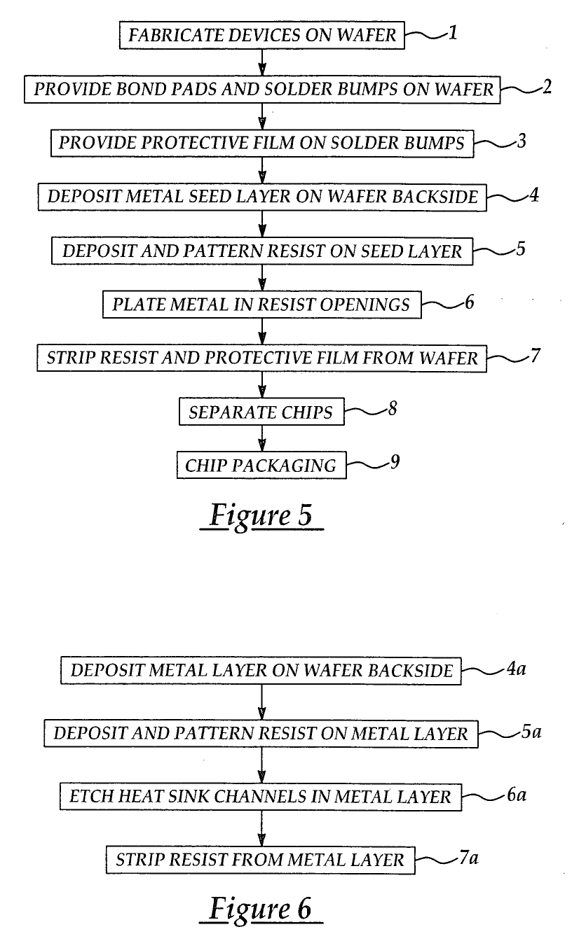

Referring next to FIG. 5, wherein a flow diagram which summarizes sequential process steps according to the method of the present invention is shown. In process step 1, IC devices are fabricated on a semiconductor wafer. In process step 2, bond pads are provided in electrical communication with the IC devices and solder bumps are formed on the bump pads. In process step 3, a protective film laminate is formed on the solder bumps to protect the solder bumps during the subsequent heat sink fabrication process.

In process step 4, a metal seed layer is deposited on the backside of the wafer. In process step 5, a photoresist is layered and patterned on the seed layer. In process step 6, a metal is plated onto the seed layer and in the photoresist openings of the photoresist. In process step 7, the photoresist and protective film are stripped from the wafer. In process step 8, multiple IC chips previously fabricated on the wafer are separated from each other in a die separation process, with a heat sink remaining on the backside of each IC chip. In process step 9, the chip packaging process is completed, with each IC chip bonded to a substrate such as a printed circuit board and assembly of the resulting flip chip into an electronic product.

Referring next to FIG. 6, wherein a flow diagram which summarizes sequential process steps of an alternative method according to the present invention is shown. Process steps 1-3 of the alternative method correspond to steps 1-3, respectively, of the method heretofore described with respect to FIG. 5. However, in process step 4a, a metal layer is deposited on the backside of the wafer. In process step 5a, a photoresist layer is deposited on the metal layer and then patterned to include photoresist openings which define the size and configuration of heat sink channels to be subsequently etched in the metal layer. In process step 6a, the portions of the metal layer which are exposed through the photoresist openings are etched to form the meshwork of heat sink channels in the metal layer. The portions of the metal layer which are covered by the photoresist remain intact and form the columns of the heat sink. In process steps 7 and 8 of the alternative method, the IC chips are separated and packaged, as heretofore described with respect to steps 7 and 8, respectively, of the method of FIG. 5.

While the preferred embodiments of the invention have been described above, it will be recognized and understood that various modifications can be made in the invention and the appended claims are intended to cover all such modifications which may fall within the spirit and scope of the invention.

1. A wafer level package having an integrated heat sink-formed on a wafer backside comprising:
a semiconductor wafer having said wafer backside and a patterned surface;
a heat sink on said wafer backside;
a plurality of solder bumps provided on said patterned surface; and
a substrate having a plurality of solder bumps provided in electrical contact with said plurality of solder bumps provided on said patterned surface.

2. The water level package of claim 1, wherein said heat sink on said wafer backside is formed by depositing a heat dissipating material over said wafer backside and etching the same.

3. The wafer level package of claim 1 wherein said heat sink on said wafer backside comprises a metal seed layer on said wafer backside and a metal layer on said seed layer.

4. The wafer level package of claim 1 wherein said heat sink comprises a plurality of columns and a meshwork of heat sink channels extending between said plurality of columns.

5. The wafer level package of claim 1 further comprising an epoxy provided between said patterned surface and said substrate.

6. The wafer level package of claim 1, wherein said a heat sink is a thermally-conductive metal selected from the group consisting of copper, silver and titanium.

7. The wafer level package of claim 1 wherein said semiconductor wafer is a flip chip.

8. A method of dissipating heat from an IC chip, comprising:
providing a semiconductor wafer having a wafer backside and a patterned surface.
providing a plurality of IC chips on said wafer by fabricating integrated circuits on said patterned surface;
fabricating a heat sink on said wafer backside; and
separating said IC chips from each other, whereby said heat sink is provided on each of said IC chips.

9. The method of claim 8 wherein said fabricating a heat sink on said wafer backside comprises providing a metal seed layer on said wafer backside, providing a patterned photoresist layer on said seed layer, depositing a metal on said seed layer, and stripping said photoresist layer from said seed layer.

10. The method of claim 8 wherein said heat sink comprises a plurality of columns and a meshwork of heat sink channels extending between said plurality of columns.

11. The method of claim 8 wherein said heat sink is a thermally-conductive metal selected from the group consisting of copper, silver and titanium.

12. The method of claim 8 wherein said fabricating a heat sink on said wafer backside comprises providing a metal layer on said wafer backside and etching said metal layer.

13. The method of claim 8, further comprising providing a plurality of solder bumps on said patterned surface in electrical contact with said integrated circuits prior to said fabricating a heat sink of said wafer backside.

14. A method of dissipating heat from an IC chip, comprising:
providing a semiconductor wafer having a wafer backside and a patterned surface;
providing a plurality of IC chips on said wafer by fabricating integrated circuits on said patterned surface;
fabricating a heat sink on said wafer backside;
separating said IC chips from other, whereby said heat sink is provided on each of said IC chips;
packaging each of said IC chips by providing a plurality of substrates and bonding said IC chips to said plurality of substrates, respectively.

15. The method of claim 14 wherein said fabricating a heat sink on said wafer backside comprises providing a metal seed layer on said wafer backside, providing a patterned photoresist layer on said seed layer, depositing a metal on said seed layer, and stripping said photoresist layer from said seed layer.

16. The method of claim 14 wherein said fabricating a heat sink on said wafer backside comprises providing a metal layer on said wafer backside and etching said metal layer.

17. The method of claim 14 wherein said heat sink comprises a plurality of columns and a meshwork of heat sink channels extending between said plurality of columns.
